(19) United States
(12) Patent Application Publication
(10) Pub. No.: US 2025/0362438 A1
(43) Pub. Date: Nov. 27, 2025

(54) LONG-PASS FILTER STRUCTURES FOR LIGHT-EMITTING DIODES

(71) Applicant: CreeLED, Inc., Durham, NC (US)

(72) Inventors: David Suich, Durham, NC (US); Austin Spencer, Durham, NC (US); Thomas Celano, Cary, NC (US); Colin Blakely, Raleigh, NC (US)

(21) Appl. No.: 18/669,969

(22) Filed: May 21, 2024

(51) Int. Cl. G02B 5/26; H01L 33/50; H01L 33/52

(52) U.S. Cl. CPC G02B 5/26; H10H 20/8511; H10H 20/852

(57) ABSTRACT

Solid-state lighting devices and more particularly long pass filter structures for light-emitting diodes are disclosed. LED packages are disclosed that include one or more LED chips, lumiphoric materials, and integrated filter structures for reducing emissions below certain wavelengths, for example emissions that may have adverse effects on normal wildlife behavior, such as nesting sea turtles and/or newly-hatched sea turtles. Exemplary filter structures are disclosed with specific arrangements for preferentially reflecting undesired wavelengths, such as those of the one or more LED chips, while preferentially transmitting intended wavelengths, such as wavelength-converted wavelengths from lumiphoric materials. Exemplary filter structures include various layers with various tailored optical thicknesses for light entrance, middle, and light exit portions of filter structures.

### FIELD OF THE DISCLOSURE

The present disclosure relates to solid-state lighting devices and more particularly to long-pass filter structures for light-emitting diodes.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LED technology is increasingly being developed for providing general illumination in a variety of environments. LED manufacturers must balance multiple application tradeoffs including efficacy, longevity, spectral optimization, and optical distribution in view of potential environmental impacts.

The art continues to seek improved LEDs and solid-state lighting devices having desirable illumination characteristics capable of overcoming challenges associated with conventional lighting devices.

### SUMMARY

The present disclosure relates to solid-state lighting devices and more particularly to long pass filter structures for light-emitting diodes (LEDs). LED packages are disclosed that include one or more LED chips, lumiphoric materials, and integrated filter structures for reducing emissions below certain wavelengths, for example emissions that may have adverse effects on normal wildlife behavior, such as nesting sea turtles and/or newly-hatched sea turtles. Exemplary filter structures are disclosed with specific arrangements for preferentially reflecting undesired wavelengths, such as those of the one or more LED chips, while preferentially transmitting intended wavelengths, such as wavelength-converted wavelengths from lumiphoric materials. Exemplary filter structures include various layers with various tailored optical thicknesses for light entrance, middle, and light exit portions of filter structures.

In one aspect, an LED package comprises: at least one LED chip configured to emit light with a first peak wavelength that is below 560 nanometers (nm); a lumiphoric material arranged to convert at least a portion of the light of the first peak wavelength to light with a second peak wavelength that is greater than the first peak wavelength; and a filter structure on the lumiphoric material, the filter structure configured to be more reflective than transmissive to light below 560 nm and more transmissive than reflective to light above 560 nm, the filter structure comprising: a plurality of first dielectric layers of a first material in an alternating arrangement with a plurality of second dielectric layers of a second material that is different than the first material, wherein a first layer of the plurality of first dielectric layers is positioned closer to the at least one LED chip than any other layer of the plurality of first dielectric layers, and the first layer of the plurality of first dielectric layers is at least two times thicker than a thinnest layer of the plurality of first dielectric layers. In certain embodiments, the first layer of the plurality of first dielectric layers is at least three times thicker than the thinnest layer of the plurality of first dielectric layers. In certain embodiments, the first layer of the plurality of first dielectric layers is a thickest layer of the plurality of first dielectric layers. In certain embodiments, a last layer of the plurality of first dielectric layers is positioned farther away from the at least one LED chip than any other layer of the plurality of first dielectric layers, and the last layer of the plurality of first dielectric layers is at least two time thicker than the thinnest layer of the plurality of first dielectric layers. In certain embodiments, a first layer of the plurality of second dielectric layers is positioned closer to the at least one LED chip than any other layer of the plurality of second dielectric layers, and the first layer of the plurality of second dielectric layers is thicker than any other layer of the plurality of second dielectric layers. In certain embodiments, the first layer of the plurality of first dielectric layers is thicker than the first layer of the plurality of second dielectric layers. In certain embodiments, a second layer of the plurality of first dielectric layers is positioned between the first layer of the plurality of first dielectric layers and other layers of the plurality of first dielectric layers, and the second layer of the plurality of first dielectric layers is at least two times thicker than the thinnest layer of the plurality of first dielectric layers. In certain embodiments, a last layer of the plurality of second dielectric layers is positioned farther away from the at least one LED chip than any other layer of the plurality of second dielectric layers, and the last layer of the plurality of second dielectric layers is a thickest layer of the filter structure.

In certain embodiments, the LED package further comprises a light-altering material positioned about lateral edges of the at least one LED chip, the lumiphoric material, and the filter structure. The LED package may further comprise a lens over the at least one LED chip and one or more portions of the light-altering material. In certain embodiments, the lens is between the lumiphoric material and the filter structure, and the filter structure forms a nonplanar shape that corresponds with a shape of the lens.

In certain embodiments, the LED package further comprises a cover structure that includes a support element, wherein the filter structure is formed as part of the cover structure. In certain embodiments, the filter structure is between the support element and the lumiphoric material. In certain embodiments, the support element is between the filter structure and the lumiphoric material. In certain embodiments, the filter structure is a first filter structure and the cover structure further comprise a second filter structure, wherein the support element is between the first filter structure and the second filter structure.

In certain embodiments, a total number of a sum of the plurality of first dielectric layers and the plurality of the second dielectric layers is in a range from eight layers to twenty-four layers.

The LED package may further comprise a support structure, wherein the at least one LED is mounted on the support structure, and a portion of the lumiphoric material and a portion of the filter structure cover portions of the support structure that are adjacent the at least one LED chip.

The LED package may further comprise: a support structure on which the at least one LED is mounted; and a lens between the filter structure and the lumiphoric material, wherein the lens forms a cavity over the submount, the at least one LED is positioned within the cavity, and the filter structure forms a nonplanar shape that corresponds with a shape of the lens.

In another aspect, an LED package comprises: at least one LED chip configured to emit light with a first peak wavelength; a lumiphoric material arranged to convert at least a portion of the light of the first peak wavelength to light with a second peak wavelength that is different than the first peak wavelength; and a filter structure on the lumiphoric material, the filter structure configured to be more reflective than transmissive to light of the first peak wavelength and more transmissive than reflective to light of the second peak wavelength, the filter structure comprising: a plurality of first dielectric layers of a first material in an alternating arrangement with a plurality of second dielectric layers of a second material that is different than the first material, wherein a last layer of the plurality of second dielectric layers is positioned farther away from the at least one LED chip than any other layer of the plurality of second dielectric layers, and the last layer of the plurality of second dielectric layers is a thickest layer of the filter structure. In certain embodiments, the last layer of the plurality of second dielectric layers is at least two times thicker than a thinnest layer of the plurality of second dielectric layers. In certain embodiments, the last layer of the plurality of second dielectric layers is at least four times thicker than a thinnest layer of the plurality of second dielectric layers. In certain embodiments, a first layer of the plurality of first dielectric layers is positioned closer to the at least one LED chip than any other layer of the plurality of first dielectric layers and a last layer of the plurality of first dielectric layers is positioned farther away from the at least one LED chip than any other layer of the plurality of first dielectric layers, and the first layer and a second layer of the plurality of first dielectric layers are both at least two times thicker than a thinnest layer of the plurality of first dielectric layers. In certain embodiments, a total number of a sum of the plurality of first dielectric layers and the plurality of the second dielectric layers is in a range from eight layers to twenty-four layers.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a spectral plot of a light-emitting diode (LED)-based device according to aspects of the present disclosure. The x-axis indicates the wavelength in nanometers (nm) while the y-axis indicates relative radiant power percentage.

FIG. 1B is a schematic illustration showing light transmissive and light reflective behavior of filter structures of the present disclosure that may be implemented with the emission spectrum of FIG. 1A.

FIG. 2 is a cross-sectional view of an LED package that includes an LED chip with a lumiphoric material and a filter structure according to aspects of the present disclosure.

FIG. 3 is a cross-sectional view of an LED package that is similar to the LED package of FIG. 2 and further includes a lens according to aspects of the present disclosure.

FIG. 4 is a general cross-sectional view of an LED package that is similar to the LED package of FIG. 2.

FIG. 5 is a general cross-sectional view of an LED package that is similar to the LED package of FIG. 4 for embodiments where a support element is positioned between the filter structure and the lumiphoric material.

FIG. 6 is a general cross-sectional view of an LED package that is similar to the LED package of FIG. 4 for embodiments that include two filter structures.

FIG. 7 is a spectral plot illustrating application of filter structures according to aspects of the present disclosure.

FIG. 8A is a cross-sectional view of an exemplary eight-layer arrangement for the filter structure according to aspects of the present disclosure.

FIG. 8B is a spectral plot illustrating simulated transmittance and reflectance for the filter structure of FIG. 8A.

FIG. 9A is a cross-sectional view of an exemplary twelve-layer arrangement for the filter structure according to aspects of the present disclosure.

FIG. 9B is a spectral plot illustrating simulated transmittance and reflectance for the filter structure of FIG. 9A.

FIG. 10A is a cross-sectional view of an exemplary sixteen-layer arrangement for the filter structure according to aspects of the present disclosure.

FIG. 10B is a spectral plot illustrating simulated transmittance and reflectance for the filter structure of FIG. 10A.

FIG. 11 is a cross-sectional view of another exemplary sixteen-layer arrangement for the filter structure according to aspects of the present disclosure.

FIG. 12A is a cross-sectional view of an exemplary twenty-four-layer arrangement for the filter structure according to aspects of the present disclosure.

FIG. 12B is a spectral plot illustrating simulated transmittance and reflectance for the filter structure of FIG. 12A.

FIG. 13 is a cross-sectional view of an LED package that is similar to the LED package of FIG. 2 for embodiments that do not include the support element of FIG. 2.

FIG. 14 is a cross-sectional view of an LED package that is similar to the LED package of FIG. 13 for additional embodiments that do not include the support element of FIG. 2.

FIG. 15 is a cross-sectional view of an LED package that is similar to the LED package of FIG. 13 for embodiments where the filter structure is nonplanar above the LED chip.

FIG. 16 is a cross-sectional view of an LED package that is similar to the LED package of FIG. 13 for embodiments where the lens has a hollow shape above the LED chip.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices and more particularly to long pass filter structures for light-emitting diodes (LEDs). LED packages are disclosed that include one or more LED chips, lumiphoric materials, and integrated filter structures for reducing emissions below certain wavelengths, for example emissions that may have adverse effects on normal wildlife behavior, such as nesting sea turtles and/or newly-hatched sea turtles. Exemplary filter structures are disclosed with specific arrangements for preferentially reflecting undesired wavelengths, such as those of the one or more LED chips, while preferentially transmitting intended wavelengths, such as wavelength-converted wavelengths from lumiphoric materials. Exemplary filter structures include various layers with various tailored optical thicknesses for light entrance, middle, and light exit portions of filter structures.

An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

An LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, spectral density, etc. In certain embodiments, lumiphoric materials having cyan or green peak wavelengths may be used. In certain embodiments, the LED chip and corresponding lumiphoric material may be configured to primarily emit converted light from the lumiphoric material so that aggregate emissions include little to no perceivable emissions that correspond to the LED chip itself.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

In certain embodiments, one or more lumiphoric materials may be provided as at least a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In certain embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may comprise a generally planar upper surface that corresponds to a light emission area of the LED package. Wavelength conversion elements and cover structures may be attached to one or more LED chips using, for example, a layer of transparent adhesive. In various embodiments, wavelength conversion elements may comprise configurations such as phosphor-in-glass or ceramic phosphor plate arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements.

The present disclosure can be useful for LED chips having a variety of geometries, such as vertical and/or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface. In certain flip-chip embodiments, the growth substrate of the LED chip may form the intended light-exiting surface for the LED chip.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In certain embodiments, a “light-transmissive” material may be configured to transmit at least 50% of emitted radiation of a desired wavelength.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support member, such as a submount or a leadframe. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

LED-based light sources are increasingly used for general illumination in a variety of outdoor environments. In certain environments, artificial lighting sources at night may disrupt normal wildlife behavior. For example, sea turtles are known to orient themselves by the position of the moon as they come ashore to lay eggs. They instinctively look for dark areas to lay eggs for safe nesting while avoiding beach areas with too much light. When turtles hatch, they are typically drawn toward the ocean based on moon lighting and associated reflections from the ocean surface. When beaches are bathed in artificial light, this nesting and hatching behavior can be disrupted. For example, sea turtles may avoid laying eggs or attempt to nest in unsafe areas when disoriented by artificial lighting, and newly hatched sea turtles may attempt to travel toward artificial lighting and face increased exposure to predators. In this regard, artificial lighting along beaches can pose risks for long-term survival of various species of sea turtles.

According to aspects of the present disclosure, LED-based lighting sources are provided that reduce emissions with wavelengths below 560 nm. It is known that wavelengths below 560 nm may mimic light reflected from the ocean, thereby disorienting normal sea turtle behavior. Certain conventional solutions involve low pressure sodium lamps that may suffer from low color rendering. Conventional LED solutions include configuring active LED structure of LED chips to wavelengths of light above 560 nm, such as amber-emitting LED chips. However, such longer wavelength LED chips may suffer from poor emission efficiency and poor thermal and current droop where emission efficiency drops increase with increasing current. Furthermore, such long wavelength LED chips have typically higher costs than shorter wavelength LED chips. In this manner, LED-based lighting has been developed that combine shorter wavelength LED chips that exhibit greater emission efficiency, such as various blue wavelengths, with lumiphoric materials such as phosphors that convert blue wavelengths to emissions with peak wavelengths well above 560 nm. However, emissions from lumiphoric materials may have broader emission spectrums that provide improved color rendering but may also include undesired emissions below 560 nm. Furthermore, lumiphoric materials may not fully convert LED chip emissions such that some blue light may also escape. In this regard, secondary optics may be added at the LED fixture level that introduce absorption filters for reducing lower wavelength emissions. However, such filters at the fixture level can be bulky and expensive while also having a greater impact on overall brightness and efficiency. Accordingly, such secondary optics are not widely accepted as viable solutions for turtle-friendly lighting.

According to aspects of the present disclosure, LED packages are disclosed that include integrated filter structures for reducing wavelengths below certain wavelengths, such as below 560 nm, and such LED packages may be readily incorporated in various lighting fixtures without the need for additional elements. By providing filter structures at proximate LED chips and within individual LED packages, emission efficiency may be increased while also providing drop-in light sources for larger fixtures. In certain embodiments, exemplary LED packages include one or more LED chips configured to generate blue peak wavelengths of light, lumiphoric materials to provide wavelength-converted light above 560 nm, and filter structures with improved filtering capabilities for reducing amounts of light below 560 nm.

As used herein, a filter structure may include multiple layers or coatings with variable thickness and/or index of refraction differences that collectively provide the ability to pass certain wavelengths of light while reflecting or otherwise redirecting other wavelengths of light. In various arrangements, filter structures as described herein may include one or more of a high-pass filter structure or a long-pass filter structure configured to promote wavelengths above 560 nm to pass through while reflecting wavelengths below 560 nm. By way of non-limiting example, a filter structure may include alternating layers with alternating index of refraction materials (e.g., high-low) where relative layer thicknesses are chosen specifically to promote constructive interference for a specific wavelength band while reflecting wavelengths outside of the specific wavelength band. Filter structures according to the present disclosure may include but are not limited to one or more oxides of silicon (e.g., SiO₂), oxides of zirconium (e.g., ZrO₂), oxides of aluminum (e.g., Al₂O₃), oxides of titanium (e.g., TiO₂ or Ti₃O₅), oxides of indium (e.g., In₂O₃), indium tin oxide (ITO), silicon nitride (e.g., SiNₓ), magnesium fluoride (e.g., MgF₂), cerium fluoride (e.g., CeF₃), fluoropolymers, and combinations thereof. Specific arrangements of filter structures in LED packages are disclosed that may promote reflection of unconverted light (e.g., from an LED chip) back into lumiphoric materials within increased efficiency across multiple emission angles.

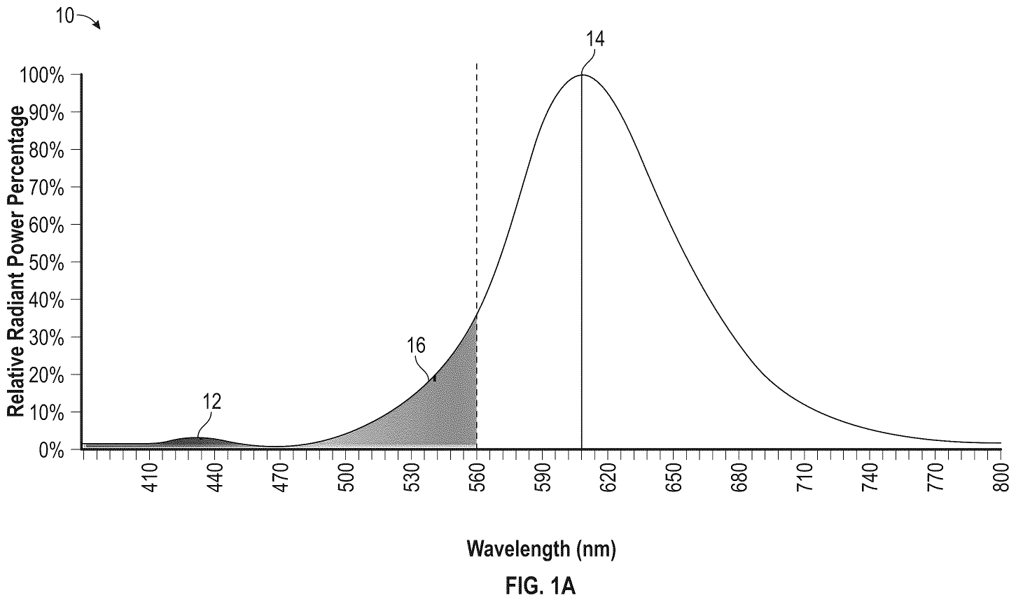

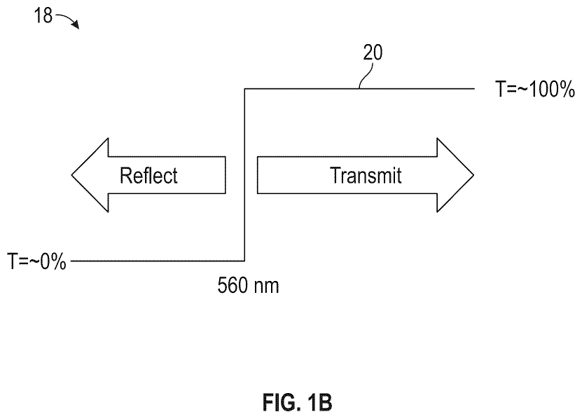

FIG. 1A is a spectral plot 10 of an LED-based device according to aspects of the present disclosure. The x-axis indicates the wavelength in nanometers (nm) while the y-axis indicates relative radiant power percentage. The LED-based device may embody an LED chip configured to emit generally blue wavelengths and a recipient lumiphoric material that converts blue wavelengths to light with longer wavelengths. In FIG. 1A, a portion of the blue wavelength from the LED chip is detectable in the overall emissions as a smaller first peak 12. Contributions from the lumiphoric material are illustrated with a much larger second peak 14. As described above, lumiphoric materials may exhibit broader emissions that include a generally larger area of wavelengths above and below the second peak 14. For reference, the wavelength of 560 nm is represented by a vertical dashed line in FIG. 1A. As illustrated, shoulder emissions 16 from the lumiphoric material and/or unconverted blue emissions (e.g., the first peak 12) may contribute to sufficient portions of the overall emission spectrum that may be disruptive to normal wildlife behavior, such as sea turtles. While the second peak 14 is illustrated as being above 560 nm, the principles described herein are applicable to any wavelength for the second peak 14 that is greater than the first peak 12 provided by the LED chip. In this manner, generally broader spectrum emissions from lumiphoric materials may position the second peak 12 below 560 nm while still providing suitable emissions above 560 nm.

FIG. 1B is a schematic illustration showing light transmissive and light reflective behavior of filter structures of the present disclosure that may be implemented with the emission spectrum of FIG. 1A. As will be described later in greater detail, filter structures are disclosed that provide increased reflectivity for wavelengths below 560 nm and increased transmittance above 560 nm. In FIG. 1B, a line 20 represents intended transmittance where portions of the emission spectrum above 560 nm exhibit as close as possible to 100% transmittance through the filter structure while wavelengths below 560 nm exhibit as close as possible to 0% transmittance.

FIG. 2 is a cross-sectional view of an LED package 22 that includes an LED chip 24 with a lumiphoric material 26 and a filter structure 28 according to aspects of the present disclosure. The LED chip 24 may include a single LED chip or a plurality of LED chips as indicated by the vertical dashed line. The lumiphoric material 26 is positioned between the LED chip 24 and the filter structure 28. In this manner, light from the LED chip 24 may readily enter the lumiphoric material 26 for wavelength conversion. The lumiphoric material 26 may embody a separate coating or film that is applied to the LED chip 24 before a cover structure 30 is attached. In other embodiments, the lumiphoric material 26 may be formed on and integrated as part of the cover structure 30 before attachment with the LED chip 24. The filter structure 28 may then permit passage of wavelength-converted light while reflecting unconverted light from the LED chip 24 back into the lumiphoric material 26, where it may be subject to wavelength conversion or absorption. In certain embodiments, the filter structure 28 may be integrated as part of a cover structure 30 of the LED package 22. The cover structure 30 may include a support element 32 that is generally light transparent as described above, and the filter structure 28 may be formed on the support element 32. The LED chip 24 may be mounted on a support structure 34 of the LED package 22. As described above, the support structure 34 may embody a submount or a lead frame structure for the LED package 22.

As further illustrated in FIG. 2, a light-altering layer 36 may be provided on the support structure 34 and surrounding lateral edges of the LED chip 24. The light-altering layer 36 may include a light-reflective material and/or a light-refracting material that effectively redirects laterally propagating light back toward a desired emission direction, such as through the cover structure 30. In certain embodiments, the light-altering layer 36 may also be positioned about lateral edges of lumiphoric material 26 and/or the filter structure 28. In this manner, the cover structure 30 forms a primary emission surface of the LED package 22 and laterally propagating light from either the LED chip 24 or the lumiphoric material 26 may be redirected for interaction with the filter structure 28. As illustrated, the light-altering layer 36 may surround lateral edges of the cover structure 30 to shape emission patterns exiting the LED package 22. For light-reflecting embodiments, the light-altering layer 36 may have a predominantly white color. Alternatively, the light-altering layer 36 may be provided with a predominantly black color to provide increased contrast for light passing through the cover structure 30.

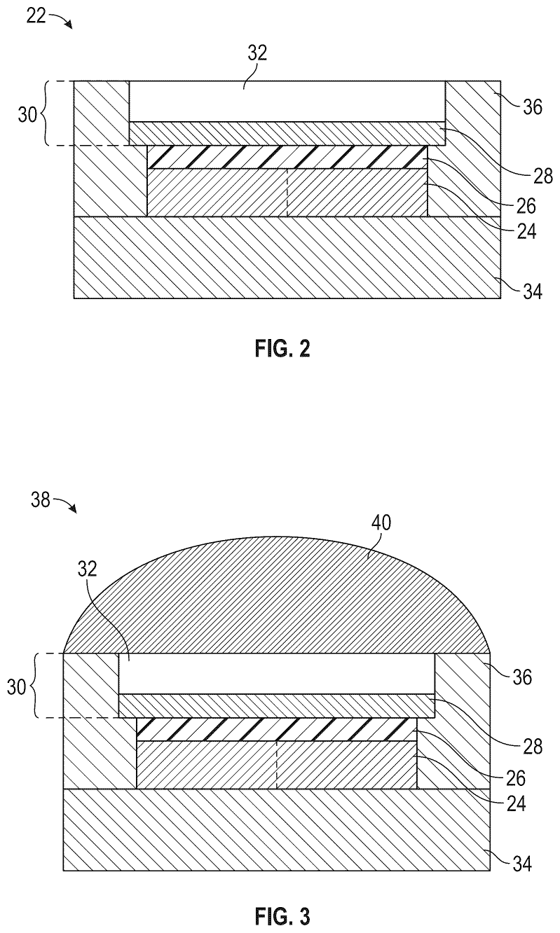

FIG. 3 is a cross-sectional view of an LED package 38 that is similar to the LED package 22 of FIG. 2 and further includes a lens 40 according to aspects of the present disclosure. The lens 40 may form any number of shapes suitable for controlling an emission pattern for the LED package 38. In certain embodiments, the lens 40 may cover one or more portions of the light-altering layer 36. The lens 40 may comprise various light-transmissive and/or light-transparent materials, including glass or silicone. In certain embodiments, the lens 40 may further comprise light-diffusing materials and/or particles.

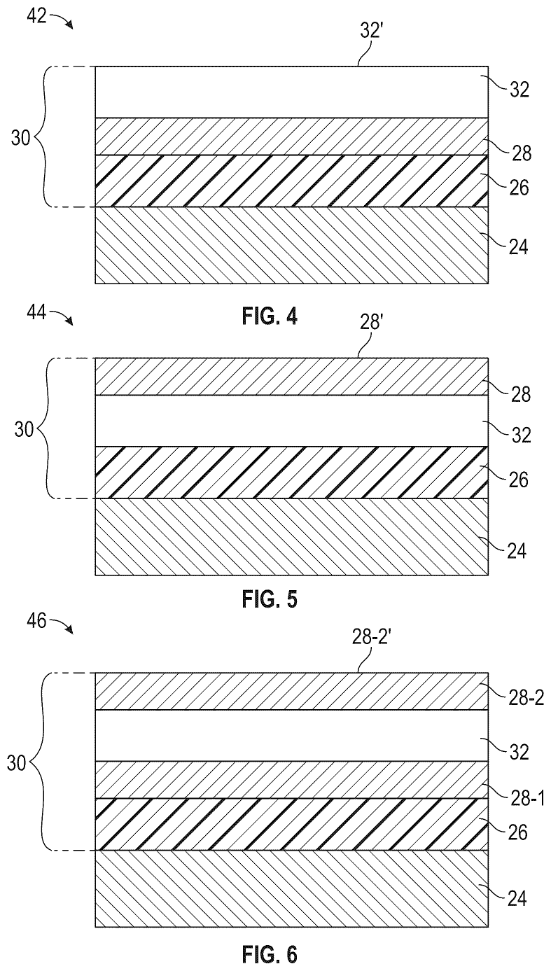

FIG. 4 is a general cross-sectional view of an LED package 42 that is similar to the LED package 22 of FIG. 2. As described above for FIG. 2, the lumiphoric material 26 may be separately formed on the LED chip 24, or the lumiphoric material 26 may be formed as part of the cover structure 30 before attachment with the LED chip 24. In FIG. 4, the lumiphoric material 26 is shown as part of the cover structure 30. In this manner, the lumiphoric material 26 may be blanket deposited on the support element 32 along with the filter structure 28 before singulation to form individual ones of the cover structure 30. As described above, the cover structure 30 may then be attached to the LED chip 24 by way of a transparent adhesive. In this manner, a top surface 32′ of the support element 32 may form an interface with air above the LED package 42. Accordingly, the support element 32 may further provide protection from the surrounding environment for the filter structure 28 and/or lumiphoric material 26.

FIG. 5 is a general cross-sectional view of an LED package 44 that is similar to the LED package 42 of FIG. 4 for embodiments where the support element 32 is positioned between the filter structure 28 and the lumiphoric material 26. In this manner, both light from the LED chip 24 and wavelength-converted light from the lumiphoric material 26 may pass through the support element 32 before interacting with the filter structure 28, and unconverted light from the LED chip 24 may be redirected back through the support element 32 toward the lumiphoric material 26. In this configuration, a top surface 28′ of the filter structure 28 may form an interface with air above the LED package 44. Accordingly, individual layers within the filter structure 28 may be configured to reduce index of refraction steps between the cover structure 30 and the surrounding environment.

FIG. 6 is a general cross-sectional view of an LED package 46 that is similar to the LED package 42 of FIG. 4 for embodiments that include two filter structures 28-1, 28-2. As illustrated, a first filter structure 28-1 may be formed between the support element 32 and the lumiphoric material 26 in a manner similar to FIG. 4, and a second filter structure 28-2 may be formed on an opposite side of the support element 32 in a manner similar to FIG. 5. Accordingly, the support element 32 may be positioned between the first and second filter structures 28-1, 28-2. In this configuration, a top surface 28-2′ of the second filter structure 28-2 may form an interface with air above the LED package 46. By having two filter structures 28-1, 28-2, further reduction in unconverted light from the LED chip 24 may be realized. Furthermore, the top surface 28-2′ of the second filter structure 28-2 may be configured to reduce index of refraction steps between the cover structure 30 and the surrounding environment. As such, the second filter structure 28-2 may not have an identical structure to the first filter structure 28-1 in certain embodiments.

The views provided in FIGS. 4 to 6 are generalized for illustrative purposes. It is understood any of the elements shown and described for FIGS. 2 and 3, including the support structure 34, the light-altering layer 36, and the lens 40 may also be implemented in any of the LED packages of FIGS. 4 to 6.

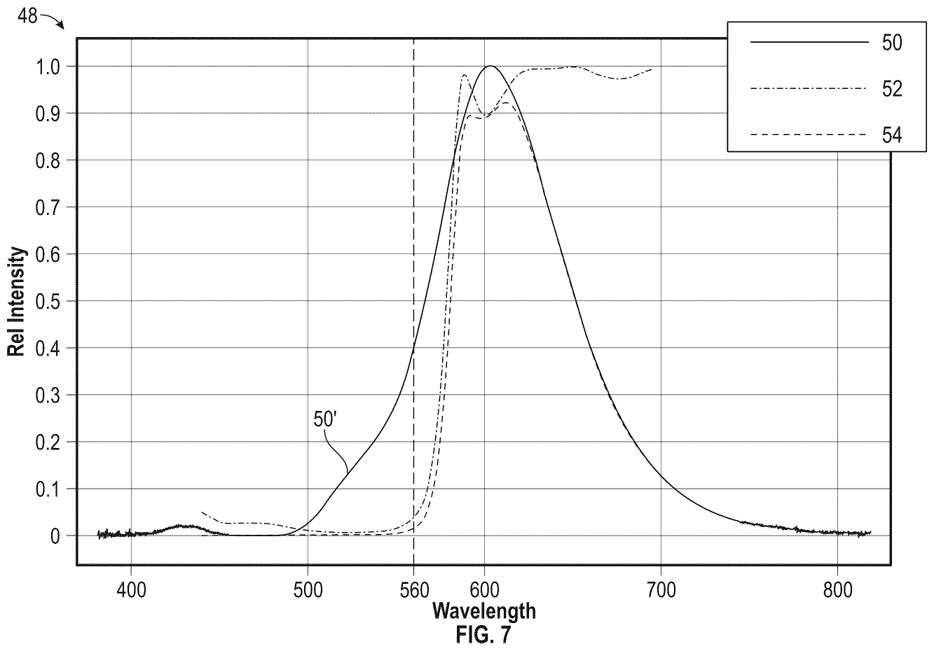

FIG. 7 is a spectral plot illustrating application of filter structures according to aspects of the present disclosure. The x-axis indicates the wavelength in nanometers (nm) while the y-axis indicates relative emission intensity. In FIG. 7, a vertical line is provided at a wavelength of 560 nm where filter structures are intended to reflect emissions below 560 nm and pass emissions above 560 nm. A first spectral line 50 represents measured emissions of a wavelength-converted LED package that includes a blue LED chip with an amber lumiphoric material (e.g., phosphor material) and does not include a filter structure. As illustrated, while the first spectral line 50 exhibits a peak wavelength above 560 nm, notable shoulder emissions 50′ are present below 560 nm. Such shoulder emissions 50′ may be undesirable in the context of wildlife disruption, including night illumination proximate sea turtle nesting locations. A second spectral line 52 represents simulated transmission for a filter structure configured to preferentially pass wavelengths above 560 nm according to the present disclosure. As illustrated, the second spectral line 52 exhibits a sharp increase in emission intensity above 560 nm. A third spectral line 54 represents application of the simulated filter transmission of the second spectral line 52 to the measured emissions of the first spectral line 50. As illustrated, shoulder emissions 50′ are substantially removed, thereby providing a suitable emission profile for outdoor applications such as illumination proximate sea turtle nesting locations.

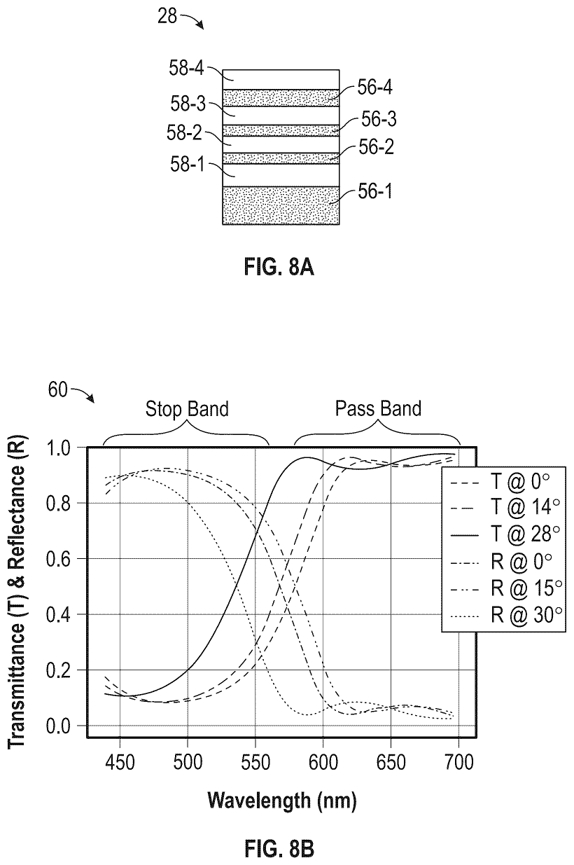

FIGS. 8A to 12B represent various configurations and spectral responses of that may be implemented for the filter structures 28 of any of the previous embodiments. As will be described below in greater detail, the various configurations for the filter structure 28 include alternating first and second dielectric layers of different materials, such as different ones of oxides of silicon (e.g., SiO₂), oxides of zirconium (e.g., ZrO₂), oxides of aluminum (e.g., Al₂O₃), oxides of titanium (e.g., TiO₂ or Ti₃O₅), oxides of indium (e.g., In₂O₃), ITO, silicon nitride (e.g., SiNₓ), magnesium fluoride (e.g., MgF₂), cerium fluoride (e.g., CeF₃), and fluoropolymers. In the context of FIGS. 8A, 9A, and 10A, layer stacks are provided with alternating individual layers numbered sequentially as 56-1, 58-1, 56-2, 58-2, and so on. As labeled, the layer labeled 56-1 is positioned closest to the LED chip 24 or lumiphoric material 26 of FIG. 2 than any other layer, the layer labeled 58-2 is the next closest layer to the LED chip 24 and the lumiphoric material 26 of FIG. 2, and so on. In this manner, the layer 56-1 may form an interface with the lumiphoric material 26 in certain embodiments. Furthermore, a top layer on each of the stacks of FIGS. 8A, 9A, and 10A may be positioned closest to the support element 32 of FIG. 2. For the alternative arrangements of FIG. 5 and for the filter structure 28-2 of FIG. 6, the layer 56-1 may be closest to the support element 32 and the top layer may be positioned closest to air or a surrounding environment. In certain embodiments, the layer 56-1 that is closest to the lumiphoric material 26 may have an index of refraction that is more closely matched to silicone, which is typically used as a binder for lumiphoric materials, and the layer 58-4 that is closest to the support element 32 of FIG. 2 may have an index of refraction more closely matched to glass. In this regard, entrance and exit areas of filter structures 28 may be configured to reduce internal reflections at such interfaces and middle portions of filter structures may be specifically configured to reflect certain wavelengths and pass other wavelengths of interest.

By having alternating dielectric layers of different materials, index of refraction steps are formed therebetween to promote targeted reflection of wavelengths below 560 nm. Furthermore, thicknesses of individual dielectric layers having the same material may be varied to tailor optical thicknesses and index of refraction steps within different portions of the filter structures 28. The optical thickness for each dielectric layer may be defined as the product of the refractive index of the material and a geometric length the path of light travels within the dielectric layer. Accordingly, the optical thickness of a dielectric layer of the same material may be changed by increasing or decreasing the layer thickness. In certain embodiments, a dielectric layer with a larger optical thickness may generally promote TIR of light having shallower angles of incidence, such as between 0 and 15 degrees, than another dielectric layer with a smaller optical thickness. Accordingly, a plurality of dielectric layers with varying optical thicknesses allow some dielectric layers to reflect more light of shallower angles of incidence while having other dielectric layers that reflect more light at greater angles of incidence, thus providing the plurality of dielectric layers with increased total reflection of the targeted wavelengths over all angles.

FIG. 8A is a cross-sectional view of an exemplary eight-layer arrangement for the filter structure 28 according to aspects of the present disclosure. In FIG. 8A, the filter structure includes a plurality of first dielectric layers 56-1 to 56-4 in an alternating arrangement with a plurality of second dielectric layers 58-1 to 58-4. In FIG. 8A, the first layer 56-1 of the plurality of first dielectric layers 56-1 to 56-4 is positioned closest to the LED chip (i.e., 24 of FIG. 2) and forms a light entrance side of the filter structure 28 while a fourth dielectric layer 58-4 of the plurality of second dielectric layers 58-1 to 58-4 is positioned farthest from the LED chip (i.e., 24 of FIG. 2) and thereby forms a light exit side of the filter structure 28. In certain embodiments, the first dielectric layers 56-1 to 56-4 include a first material that is different from a second material of the second dielectric layers 58-1 to 58-4 to form index of refraction steps therebetween. By way of example, the first dielectric layers 56-1 to 56-4 may comprise Ti₃O₅ and the second dielectric layers 58-1 to 58-4 may comprise SiO₂. In this manner, the layer 56-1 that is closest to the lumiphoric material 26 may have an index of refraction that is more closely matched to silicone, which is typically used as a binder for lumiphoric materials, and the layer 58-4 that is closest to the support element 32 of FIG. 2 may have an index of refraction more closely matched to glass. Accordingly, an interface between the layer 56-1 and underlying lumiphoric material may be configured to permit light to pass into the filter structure 28, and an interface between the layer 58-4 and the support element 32 of FIG. 2 may be configured to permit light that is not reflected within the filter structure 28 to pass. As further illustrated in FIG. 8A, the first dielectric layers 56-1 to 56-4 have varying thicknesses and the second dielectric layers 58-1 to 58-4 have varying thicknesses to promote increased reflection at different angles of incidence.

In FIG. 8A, the first layer 56-1 is thicker than a thinnest layer (e.g., 56-3) of the other first dielectric layers 56-2 to 56-4. In certain embodiments, the first layer 56-1 is at least two times or at least three times thicker than a thinnest layer (e.g., 56-3) of any of the other first dielectric layers 56-2 to 56-4. In this manner, light with wider angles of incidence may be permitted to enter the filter structure 28 by passing through the first layer 56-1. In certain embodiments, the first layer 56-1 is the thickest layer of the entire filter structure 28. By way of example, the first layer 56-1 may have a thickness that is in a range from 150 nm to 450 nm while the thinnest layer 56-3 of the first dielectric layers 56-1 to 56-4 may have a thickness that is less than 50 nm. In a similar manner, a first layer 58-1 of the plurality of second dielectric layers 58-1 to 58-4 is positioned closest to the LED chip (i.e., 24 of FIG. 2) than any of the other second dielectric layers 58-2 to 58-4. In FIG. 8A, the first layer 58-1 is a thickest layer of the plurality of second dielectric layers 58-1 to 58-4. In certain embodiments, the first layer 56-1 is positioned closest to the LED chip and is a thickest layer of the entire filter structure.

FIG. 8B is a spectral plot 60 illustrating simulated transmittance and reflectance for the filter structure 28 of FIG. 8A. The x-axis indicates the wavelength in nanometers (nm). The y-axis indicates emission intensity relative to transmittance and reflectance across the wavelength range, where a value of 0 represents 100% reflectance and a value of 1.0 represents 100% transmittance. A stop band and a pass band are generally indicated on opposing sides of about 560 nm. The transmittance is plotted for angles of incidence of 0, 14, and 28 degrees while the reflectance is plotted for angles of incidence of 0, 15, and 30 degrees. As illustrated, shallower angles of incidence (e.g., 15 degrees or below) demonstrate sharper transitions from the stop band to the pass band than the wide angles of incidence (e.g., 28 degrees or above).

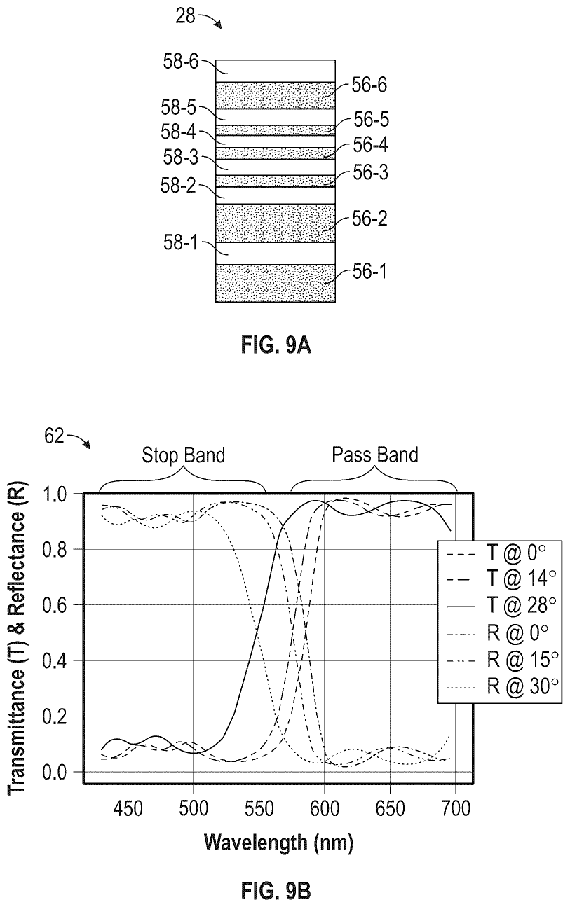

FIG. 9A is a cross-sectional view of an exemplary twelve-layer arrangement for the filter structure 28 according to aspects of the present disclosure. As with FIG. 8A, the first layer 56-1 of the plurality of first dielectric layers 56-1 to 56-6 in FIG. 9A forms a light entrance side of the filter structure 28 while a sixth dielectric layer 58-6 of the plurality of second dielectric layers 58-1 to 58-6 forms a light exit side of the filter structure 28. In certain embodiments, the first dielectric layers 56-1 to 56-6 include a first material that is different from a second material of the second dielectric layers 58-1 to 58-6 to form index of refraction steps therebetween.

In FIG. 9A, much like the first layer 56-1, a second layer 56-2 of the first dielectric layers 56-1 to 56-6 is also formed with substantially increased thickness relative to the remainder of the filter structure 28. In certain embodiments, the first layer 56-1 and the second layer 56-2 are each at least two times, or at least three times, or at least four times thicker than a thinnest layer (e.g., 56-5) of any of the other first dielectric layers 56-2 to 56-6. By way of example, the first layer 56-1 and the second layer 56-2 may each have a thickness that is in a range from 250 nm to 450 nm while the thinnest layer 56-5 of the first dielectric layers 56-1 to 56-6 may have a thickness that is less than 60 nm. As further illustrated in FIG. 9A, middle layers 56-3 to 56-5 of the first dielectric layers 56-1 to 56-6 and middle layers 58-2 to 58-5 of the second dielectric layers 58-1 to 58-6 are generally thinner than light entrance layers 56-1, 58-1, and 56-2, and generally thinner than the light exit layers 56-6 and 58-6. In this manner, the combined middle layers 56-3 to 56-6 and 58-2 to 58-5 form thin alternating layers that provided increased numbers of interfaces to promote targeted reflections at desired wavelengths, such as less than 560 nm. In this manner, the entrance and exit layers as identified above may serve to promote antireflective properties for all wavelengths at various emission angles. Accordingly, all wavelengths may generally enter the filter structure 28, the middle layers may sever to selectively reflect wavelengths below 560 nm, and wavelengths that pass through the middle layers may generally exit the filter structure 28 with increased efficiency.

FIG. 9B is a spectral plot 62 illustrating simulated transmittance and reflectance for the filter structure 28 of FIG. 9A. The x-axis indicates the wavelength in nanometers (nm). The y-axis indicates emission intensity relative to transmittance and reflectance across the wavelength range, where a value of 0 represents 100% reflectance and a value of 1.0 represents 100% transmittance. A stop band and a pass band are generally indicated on opposing sides of about 560 nm. The transmittance is plotted for angles of incidence of 0, 14, and 28 degrees while the reflectance is plotted for angles of incidence of 0, 15, and 30 degrees. As illustrated, shallower angles of incidence (e.g., 15 degrees or below) demonstrate sharper transitions from the stop band to the pass band than the wide angles of incidence (e.g., 28 degrees or above). In comparison to FIG. 8B, the twelve-layer structure of FIG. 9B exhibits a sharper transition even for the wide angles of incidence with a reduction in shoulder emissions thereof.

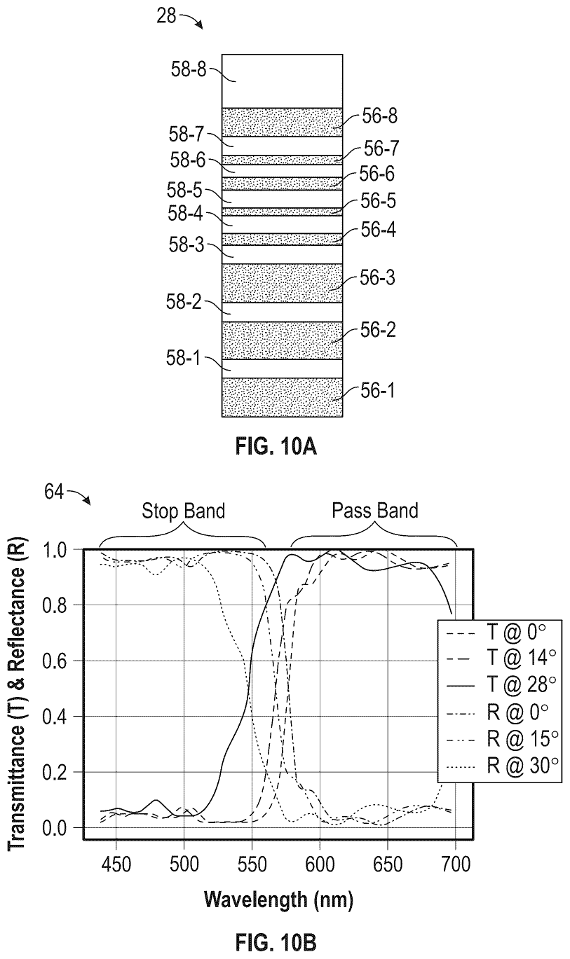

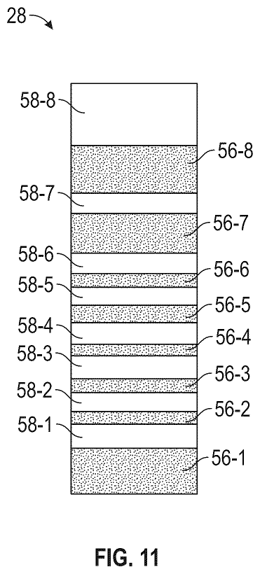

FIG. 10A is a cross-sectional view of an exemplary sixteen-layer arrangement for the filter structure 28 according to aspects of the present disclosure. As with FIG. 8A, the first layer 56-1 of the plurality of first dielectric layers 56-1 to 56-8 in FIG. 10A forms a light entrance side of the filter structure 28 while an eighth dielectric layer 58-8 of the plurality of second dielectric layers 58-1 to 58-8 forms a light exit side of the filter structure 28. In certain embodiments, the first dielectric layers 56-1 to 56-8 include a first material that is different from a second material of the second dielectric layers 58-1 to 58-8 to form index of refraction steps therebetween. In FIG. 10A, much like the first and second layers 56-1 and 56-2, a third layer 56-3 of the first dielectric layers 56-1 to 56-8 is also formed with substantially increased thickness relative to the remainder of the filter structure 28. In certain embodiments, the first layer 56-1, the second layer 56-2, and the third layer 56-3 are each at least two times, or at least three times, or at least four times thicker than a thinnest layer (e.g., 56-5) of any of the other first dielectric layers 56-4 to 56-8. By way of example, the first layer 56-1, the second layer 56-2, and the third layer 56-3 may each have a thickness that is in a range from 250 nm to 450 nm while the thinnest layer 56-5 of the first dielectric layers 56-1 to 56-8 may have a thickness that is less than 60 nm. Additionally, the topmost or last layer (i.e., 58-8) is a thickest layer of the filter structure 28, thereby promoting increased transmittance of light that is not reflected within the filter structure 28. The last layer 58-8 may be at least two times thicker, or at least three times thicker, or at least eight times thicker than a thinnest layer (e.g., 58-6) of the other second dielectric layers 58-1 to 58-7. In a similar manner as FIG. 9A, the middle layers (e.g., 56-4 to 56-6 and 58-2 to 58-7) are generally thinner and form increased numbers of interfaces to promote targeted reflection at desired wavelengths, such as below 560 nm.

As further illustrated in FIG. 10A, interfaces between middle portions (e.g., layers 56-4 to 56-6 and 58-2 to 58-7) and the light entrance portions (e.g., layers 56-1 to 56-3 and 58-1) and/or light exit portions (e.g., layers 56-8 and 58-8) may further provide index of refraction steps for promoting sharper transitions of the reflection bands and enhancing transmittance in the pass bands.

FIG. 10B is a spectral plot 64 illustrating simulated transmittance and reflectance for the filter structure 28 of FIG. 10A. The x-axis indicates the wavelength in nanometers (nm). The y-axis indicates emission intensity relative to transmittance and reflectance across the wavelength range, where a value of 0 represents 100% reflectance and a value of 1.0 represents 100% transmittance. A stop band and a pass band are generally indicated on opposing sides of about 560 nm. The transmittance is plotted for angles of incidence of 0, 14, and 28 degrees while the reflectance is plotted for angles of incidence of 0, 15, and 30 degrees. As illustrated, shallower angles of incidence (e.g., 15 degrees or below) demonstrate sharper transitions from the stop band to the pass band than the wide angles of incidence (e.g., 28 degrees or above). In comparison to FIG. 9B, the sixteen-layer structure of FIG. 10B exhibits an even sharper transition for the wide angles of incidence with a reduction in shoulder emissions thereof.

FIG. 11 is a cross-sectional view of another exemplary sixteen-layer arrangement for the filter structure 28 according to aspects of the present disclosure. As with FIG. 10A, the first layer 56-1 of the plurality of first dielectric layers 56-1 to 56-8 in FIG. 11 forms a light entrance side of the filter structure 28 while an eighth dielectric layer 58-8 of the plurality of second dielectric layers 58-1 to 58-8 forms a light exit side of the filter structure 28. In certain embodiments, the first dielectric layers 56-1 to 56-8 include a first material that is different from a second material of the second dielectric layers 58-1 to 58-8 to form index of refraction steps therebetween. In FIG. 11, the first layer 56-1 and last layer 56-8 are thicker than any other first dielectric layers 56-2 to 56-7, such as at least two times, or at least three times, or at least four times thicker than a thinnest layer (e.g., 56-5) of any of the other first dielectric layers 56-2 to 56-7. Additionally, the topmost or last layer (i.e., 58-8) is a thickest layer of the filter structure 28, thereby promoting increased transmittance of light that is not reflected within the filter structure 28. The last layer 58-8 may be at least two times thicker, or at least three times thicker, or at least eight times thicker than a thinnest layer (e.g., 58-6) of the other second dielectric layers 58-1 to 58-7. As illustrated, the middle layers (e.g., 56-2 to 56-6 and 58-2 to 58-7) are generally thinner and form increased numbers of interfaces to promote targeted reflection at desired wavelengths, such as below 560 nm. By moving the middle layers closer to the interface with the LED chip 24 and/or lumiphoric material 26 of FIG. 2, targeted wavelength reflections may occur sooner within the filter structure 28 as compared with FIG. 10A.

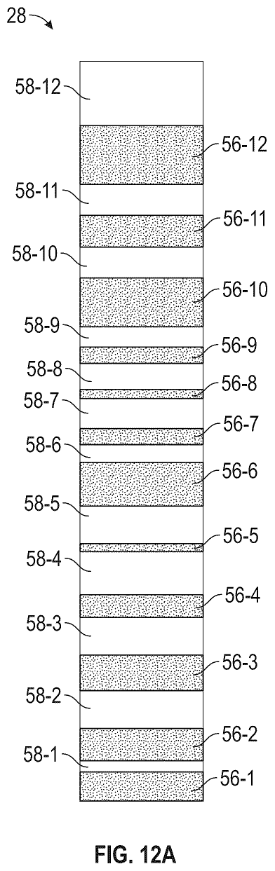

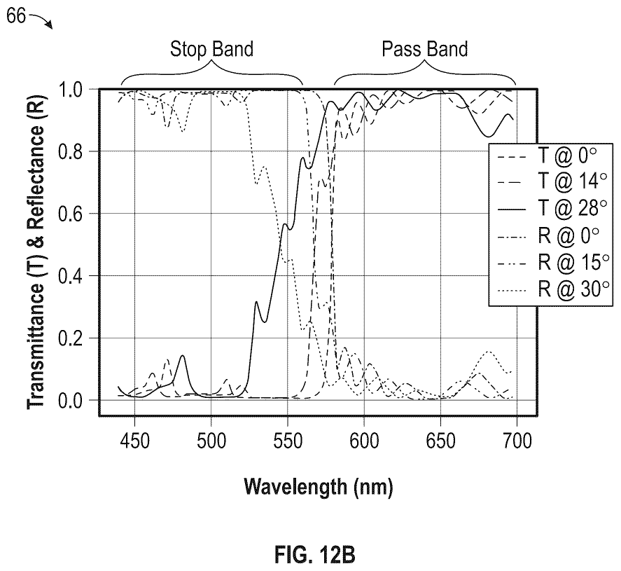

FIG. 12A is a cross-sectional view of an exemplary twenty-four-layer arrangement for the filter structure 28 according to aspects of the present disclosure. As with FIG. 10A, the first layer 56-1 of the plurality of first dielectric layers 56-1 to 56-12 in FIG. 12A forms a light entrance side of the filter structure 28 while a twelfth dielectric layer 58-12 of the plurality of second dielectric layers 58-1 to 58-12 forms a light exit side of the filter structure 28. In certain embodiments, the first dielectric layers 56-1 to 56-12 include a first material that is different from a second material of the second dielectric layers 58-1 to 58-12 to form index of refraction steps therebetween. In FIG. 12A, the topmost layer 56-12 is the thickest layer of the first dielectric layers 56-1 to 56-12 and the topmost layer 58-12 is the thickest layer of second dielectric layers 58-1 to 58-12. Furthermore, the layer 58-1 is the thinnest layer of the second dielectric layers 58-1 to 58-12. In certain embodiments, the layer 58-12 may be at least 10 times thicker than the layer 58-1. For the first dielectric layers 56-1 to 56-12, layers 56-5 and/or 56-7 are the thinnest layers. While the exit layers 56-10 to 56-12 and 58-10 to 58-12 are generally thicker compared to middle portions of the filter structure 28, the entrance side has a mixture of thick and thin layers. Accordingly, reflections at various angles of incidence may start proximate the entrance and continue through the middle layers, while the exit layers promote transmittance of desired wavelengths.

FIG. 12B is a spectral plot 66 illustrating simulated transmittance and reflectance for the filter structure 28 of FIG. 12A. The x-axis indicates the wavelength in nanometers (nm). The y-axis indicates emission intensity relative to transmittance and reflectance across the wavelength range, where a value of 0 represents 100% reflectance and a value of 1.0 represents 100% transmittance. A stop band and a pass band are generally indicated on opposing sides of about 560 nm. The transmittance is plotted for angles of incidence of 0, 14, and 28 degrees while the reflectance is plotted for angles of incidence of 0, 15, and 30 degrees. As illustrated, shallower angles of incidence (e.g., 15 degrees or below) demonstrate sharper transitions from the stop band to the pass band than the wide angles of incidence (e.g., 28 degrees or above). In comparison to FIG. 10B, the twenty-four-layer structure of FIG. 12B also exhibits a sharper transition for the wide angles of incidence with some further reductions in shoulder emissions thereof.

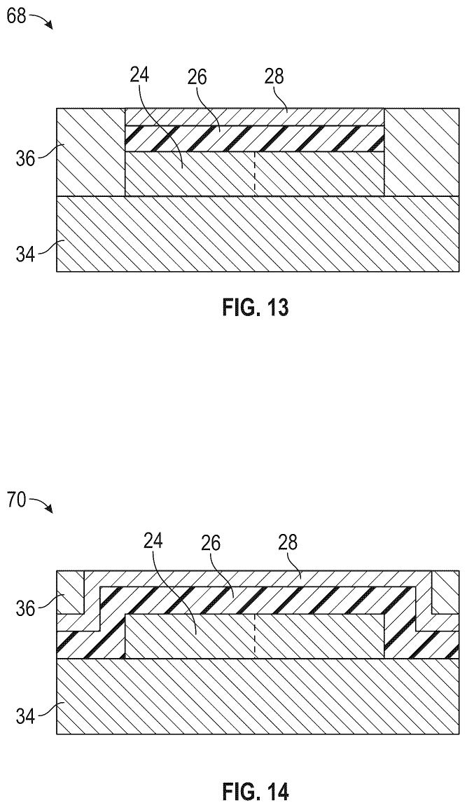

FIG. 13 is a cross-sectional view of an LED package 68 that is similar to the LED package 22 of FIG. 2 for embodiments that do not include the support element 32 of FIG. 2. As illustrated, the filter structure 28 may be provided on the lumiphoric material 26. For example, the filter structure 28 may be directly coated on a surface of the lumiphoric material 26, before or after the lumiphoric material 26 is formed on the LED chip 24. In certain embodiments, the lumiphoric material 26 may comprise a preformed structure, such as a phosphor sheet or a phosphor-in-glass structure. The filter structure 28 may be formed in bulk on the preformed structure of the lumiphoric material 26, before individual pieces are singulated and attached to corresponding ones of the LED chip 24. Alternatively, the filter structure 28 may be formed on the lumiphoric material 26 after the lumiphoric material 26 is formed on the LED chip 24. As illustrated, the light-altering layer 36 may be formed on the support structure 34 and along peripheral edges of the lumiphoric material 26 and the filter structure 28.

FIG. 14 is a cross-sectional view of an LED package 70 that is similar to the LED package 68 of FIG. 13 for additional embodiments that do not include the support element 32 of FIG. 2. In certain embodiments, the lumiphoric material 26 may embody a conformal coating on the LED chip 24 and portions of the support structure 34 that are adjacent the LED chip 24. The filter structure 28 may also embody a conformal coating on the lumiphoric material 26. For example, the lumiphoric material 26 and the filter structure 28 may be successively deposited as respective coatings on the LED chip 24 and the support structure 34. As illustrated, the light-altering layer 36 may be formed on the support structure 34 and on portions of the lumiphoric material 26 and the filter structure 28 that are laterally spaced from the LED chip 24 to further define a light-emitting surface of the LED package 70.

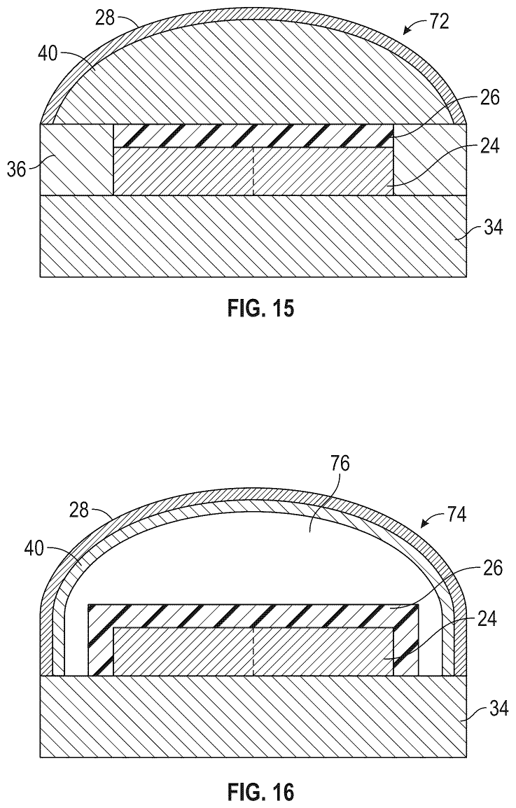

FIG. 15 is a cross-sectional view of an LED package 72 that is similar to the LED package 68 of FIG. 13 for embodiments where the filter structure 28 is nonplanar above the LED chip 24. In certain embodiments, the LED package 72 may include the lens 40 as described above for FIG. 3. The filter structure 28 may be positioned on a surface of the lens 40 such that the lens 40 effectively separates the lumiphoric material 26 from the filter structure 28. In certain embodiments, the lens 40 may form a solid structure, such as glass or the like, between the lumiphoric material 26 and the filter structure 28. The lens 40 may be formed with various nonplanar shapes, such as dome-shaped, hemispheric, ellipsoid, ellipsoid bullet, and/or shapes that include both curved and planar surfaces, such as a hemispheric or curved top portions with planar side surfaces. By positioning the filter structure 28 on the lens 40, the filter structure 28 may form with a corresponding nonplanar shape. Accordingly, incident light interacting with the filter structure 28 may first propagate through the lens 40, and increased amounts of incident light may reach the filter structure 28 with incident angles closer to normal. In contrast, a planar shape for the filter structure 28 as illustrated in other embodiments may promote a larger distribution of incident angles for other applications.

FIG. 16 is a cross-sectional view of an LED package 74 that is similar to the LED package 72 of FIG. 13 for embodiments where the lens 40 has a hollow shape above the LED chip 24. As illustrated, the lens 40 may be attached to the support structure 34 such that a cavity 76 or opening is formed over the LED chip 24 and the support structure 34. In certain embodiments, the cavity 76 may be filled with air and/or nitrogen. In certain embodiments, the cavity 76 may be under a vacuum relative to a surrounding atmosphere. In this manner, the lens 40 may effectively seal the cavity 76 about the LED chip 24, and in certain aspects, the lens 40 may form a hermetic seal. As with FIG. 15, the lens 40 may be formed with various nonplanar shapes and the filter structure 28 may also be formed with corresponding nonplanar shapes.

As described above for FIGS. 8A to 12B, optical thicknesses of various layers within the filter structure 28 may be tailored by material type and/or thickness. Total numbers of layers may be in a range from eight layers to twenty-four layers, among others. Specific configurations may tailor light entrance and/or light exit portions of the filter structure 28 for more closely matched indexes of refractions with interfaces to the filter structure. For example, more closely matched indexes may be provided with respect to the lumiphoric material 26 of FIGS. 2, 3, 4, 6 (e.g., filter structure 28-1), 13, and 14, and/or the lens 40 of FIGS. 15 and 16 for light entrances sides. For light exit sides, more closely matched indexes may be provided with respect to the support element 32 of FIGS. 2, 3, 4, and 6 (e.g., filter structure 28-1) and/or air for FIGS. 5, 6 (e.g., filter structure 28-2), 13, 14, 15, and 16. In this manner, light entrance sides may promote light to enter filter structures 28 with reduced reflections for intended emissions (e.g., light above 560 nm), middle portions of filter structures 28 may be configured to preferentially reflect certain wavelengths (e.g., less than 560 nm), while light exit sides may be configured to readily transmit the intended emissions. In still further embodiments, interfaces between middle portions of the filter structure and light entrance and/or light exit sides may further provide index steps for promoting sharper transitions of the reflection bands and enhancing transmittance in the pass bands.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
at least one LED chip configured to emit light with a first peak wavelength that is below 560 nanometers (nm);
a lumiphoric material arranged to convert at least a portion of the light of the first peak wavelength to light with a second peak wavelength that is greater than the first peak wavelength; and
a filter structure on the lumiphoric material, the filter structure configured to be more reflective than transmissive to light below 560 nm and more transmissive than reflective to light above 560 nm, the filter structure comprising:
a plurality of first dielectric layers of a first material in an alternating arrangement with a plurality of second dielectric layers of a second material that is different than the first material, wherein a first layer of the plurality of first dielectric layers is positioned closer to the at least one LED chip than any other layer of the plurality of first dielectric layers, and the first layer of the plurality of first dielectric layers is at least two times thicker than a thinnest layer of the plurality of first dielectric layers.

2. The LED package of claim 1, wherein the first layer of the plurality of first dielectric layers is at least three times thicker than the thinnest layer of the plurality of first dielectric layers.

3. The LED package of claim 1, wherein the first layer of the plurality of first dielectric layers is a thickest layer of the plurality of first dielectric layers.

4. The LED package of claim 1, wherein a last layer of the plurality of first dielectric layers is positioned farther away from the at least one LED chip than any other layer of the plurality of first dielectric layers, and the last layer of the plurality of first dielectric layers is at least two time thicker than the thinnest layer of the plurality of first dielectric layers.

5. The LED package of claim 1, wherein a first layer of the plurality of second dielectric layers is positioned closer to the at least one LED chip than any other layer of the plurality of second dielectric layers, and the first layer of the plurality of second dielectric layers is thicker than any other layer of the plurality of second dielectric layers.

6. The LED package of claim 5, wherein the first layer of the plurality of first dielectric layers is thicker than the first layer of the plurality of second dielectric layers.

7. The LED package of claim 1, wherein a second layer of the plurality of first dielectric layers is positioned between the first layer of the plurality of first dielectric layers and other layers of the plurality of first dielectric layers, and the second layer of the plurality of first dielectric layers is at least two times thicker than the thinnest layer of the plurality of first dielectric layers.

8. The LED package of claim 1, wherein a last layer of the plurality of second dielectric layers is positioned farther away from the at least one LED chip than any other layer of the plurality of second dielectric layers, and the last layer of the plurality of second dielectric layers is a thickest layer of the filter structure.

9. The LED package of claim 1, further comprising a light-altering material positioned about lateral edges of the at least one LED chip, the lumiphoric material, and the filter structure.

10. The LED package of claim 9, further comprising a lens over the at least one LED chip and one or more portions of the light-altering material.

11. The LED package of claim 10, wherein the lens is between the lumiphoric material and the filter structure, and the filter structure forms a nonplanar shape that corresponds with a shape of the lens.

12. The LED package of claim 1, further comprising a cover structure that includes a support element, wherein the filter structure is formed as part of the cover structure.

13. The LED package of claim 12, wherein the filter structure is between the support element and the lumiphoric material.

14. The LED package of claim 12, wherein the support element is between the filter structure and the lumiphoric material.

15. The LED package of claim 12, wherein the filter structure is a first filter structure and the cover structure further comprise a second filter structure, wherein the support element is between the first filter structure and the second filter structure.

16. The LED package of claim 1, wherein a total number of a sum of the plurality of first dielectric layers and the plurality of the second dielectric layers is in a range from eight layers to twenty-four layers.

17. The LED package of claim 1, further comprising a support structure, wherein the at least one LED is mounted on the support structure, and a portion of the lumiphoric material and a portion of the filter structure cover portions of the support structure that are adjacent the at least one LED chip.

18. The LED package of claim 1, further comprising:
a support structure on which the at least one LED is mounted; and
a lens between the filter structure and the lumiphoric material, wherein the lens forms a cavity over the submount, the at least one LED is positioned within the cavity, and the filter structure forms a nonplanar shape that corresponds with a shape of the lens.

19. A light-emitting diode (LED) package comprising:
at least one LED chip configured to emit light with a first peak wavelength;
a lumiphoric material arranged to convert at least a portion of the light of the first peak wavelength to light with a second peak wavelength that is different than the first peak wavelength; and
a filter structure on the lumiphoric material, the filter structure configured to be more reflective than transmissive to light of the first peak wavelength and more transmissive than reflective to light of the second peak wavelength, the filter structure comprising:
a plurality of first dielectric layers of a first material in an alternating arrangement with a plurality of second dielectric layers of a second material that is different than the first material, wherein a last layer of the plurality of second dielectric layers is positioned farther away from the at least one LED chip than any other layer of the plurality of second dielectric layers, and the last layer of the plurality of second dielectric layers is a thickest layer of the filter structure.

20. The LED package of claim 19, wherein the last layer of the plurality of second dielectric layers is at least two times thicker than a thinnest layer of the plurality of second dielectric layers.

21. The LED package of claim 19, wherein the last layer of the plurality of second dielectric layers is at least four times thicker than a thinnest layer of the plurality of second dielectric layers.

22. The LED package of claim 19, wherein a first layer of the plurality of first dielectric layers is positioned closer to the at least one LED chip than any other layer of the plurality of first dielectric layers and a last layer of the plurality of first dielectric layers is positioned farther away from the at least one LED chip than any other layer of the plurality of first dielectric layers, and the first layer and a second layer of the plurality of first dielectric layers are both at least two times thicker than a thinnest layer of the plurality of first dielectric layers.

23. The LED package of claim 19, wherein a total number of a sum of the plurality of first dielectric layers and the plurality of the second dielectric layers is in a range from eight layers to twenty-four layers.
